(19) United States
(12) Patent Application Publication
(10) Pub. No.: US 2020/0283896 A1
(43) Pub. Date: Sep. 10, 2020

(54) METHODS FOR LOW TEMPERATURE SILICIDE FORMATION

(71) Applicant: Applied Materials, Inc., Santa Clara, CA (US)

(72) Inventors: Xuebin LI, Sunnyvale, CA (US); Errol Antonio C. SANCHEZ, Tracy, CA (US); Saurabh CHOPRA, Santa Clara, CA (US)

(21) Appl. No.: 16/784,623

(22) Filed: Feb. 7, 2020

Related U.S. Application Data
(60) Provisional application No. 62/815,842, filed on Mar. 8, 2019.

(51) Int. Cl. C23C 16/455; C23C 16/02; C23C 16/06; C23C 16/24

(52) U.S. Cl. CPC C23C 16/45553; C23C 16/24; C23C 16/06; C23C 16/0209

(57) ABSTRACT

Methods for forming silicide materials and source/drain devices are provided. The methods and devices can include methods for forming silicide films, including metal silicide and metal germanide silicide films, on germanium-containing film, such as used as a pMOS layer in a source/drain contact region. In one or more embodiments, a method of processing a substrate includes positioning the substrate within a processing chamber, where the substrate contains one or more germanium-containing films, heating the substrate to a temperature of about 100° C. to about 600° C., and exposing the substrate to one or more metal precursors and one or more silicon precursors during a vapor deposition process and forming a silicide film on the germanium-containing film, where the silicide film has a conformality of about 1% to about 50% of an average thickness of the silicide film.

### CROSS-REFERENCE TO RELATED APPLICATIONS

This application claims benefit of U.S. Appl. No. 62/815,842, filed on Mar. 8, 2019, which is herein incorporated by reference in its entirety.

### BACKGROUND

### Field

Embodiments of the present disclosure generally relate to methods and for depositing materials, more particularly, to methods for forming silicide films.

### Description of the Related Art

Metal silicides or germanides are typically used in source/drain (S/D) contact area for contact resistivity reduction in metal-oxide-semiconductor (MOS) films, such as n-type (nMOS) and p-type (pMOS) films. Generally, metal silicides are used on nMOS films containing silicon and metal germanides are used on pMOS films containing germanium. However, during the chemical vapor deposition process to form metal germanides for pMOS films, the underlying germanium surfaces are often easily reacted or etched by the metal precursor which forms rough and non-conformal surfaces of the metal germanide. Also, the metal germanide has a tendency to further react with the underlying germanium in the pMOS films. As a result, too much germanium can be removed from the pMOS films causing instability of the device.

Thus, there is a need for improved methods for depositing silicides that are more conformal to the underlying surface.

### SUMMARY OF THE INVENTION

Embodiments of the present disclosure generally relate to methods for forming silicide materials and source/drain devices. The methods and devices can include methods for forming silicide films, including metal silicide and metal germanide silicide films, on germanium-containing film, such as used as a p-type metal-oxide-semiconductor (pMOS) layer in a source/drain contact region. In one or more embodiments, a method of processing a substrate includes positioning the substrate within a processing chamber, where the substrate contains one or more germanium-containing films, heating the substrate to a temperature of about 100° C. to about 600° C., and exposing the substrate to one or more metal precursors and one or more silicon precursors during a vapor deposition process and forming a silicide film on the germanium-containing film. The silicide film has a relatively high conformality, such as a conformality of about 1% to about 50% of an average thickness of the silicide film.

In some embodiments, a method of processing a substrate includes positioning the substrate within a processing chamber and heating the substrate to a temperature of about 100° C. to about 600° C. or about 200° C. to about 400° C., where the substrate contains one or more germanium-containing films. The method also includes exposing the substrate to one or more metal precursors and one or more silicon precursors during a vapor deposition process, reacting the metal precursor and a portion of the germanium-containing film to produce a metal germanium layer, and reacting the silicon precursor and the metal germanium layer to produce a silicide film on the germanium-containing film.

In other embodiments, a source/drain device contains a silicide film disposed on a germanium-containing film. The germanium-containing film contains germanium boride, germanium tin boride, silicon germanium boride, germanium gallium boride, silicon germanium gallium boride, dopants thereof, alloys thereof, or any combination thereof. The silicide film contains titanium germanium silicide and has a conformality of about 1% to about 20% of an average thickness of the silicide film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, as the disclosure may admit to other equally effective embodiments.

FIGS. 1A and 1B depict schematic, cross-sectional views of a pMOS transistor source/drain contact, as described and discussed in one or more embodiments herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods for forming silicide materials and source/drain devices are provided. The methods and devices can include methods for forming silicide films, including metal silicide and metal germanide silicide films, on germanium-containing film, such as used as a p-type metal-oxide-semiconductor (pMOS) layer in a source/drain contact region. In one or more embodiments, a method of processing a substrate includes positioning the substrate within a processing chamber, where the substrate contains one or more germanium-containing films, heating the substrate to a temperature of about 100° C. to about 600° C. or about 200° C. to about 400° C., and exposing the substrate to one or more metal precursors and one or more silicon precursors during a vapor deposition process and forming a silicide film on the germanium-containing film, where the silicide film has a conformality of about 1% to about 50% of an average thickness of the silicide film. In some examples, the silicide film can be or include one or more layers of titanium germanium silicide, nickel germanium silicide, chromium germanium silicide, cobalt germanium silicide, platinum germanium silicide, palladium germanium silicide, molybdenum germanium silicide, tungsten germanium silicide, titanium silicide, nickel silicide, chromium silicide, cobalt silicide, platinum silicide, palladium silicide, molybdenum silicide, tungsten silicide, dopants thereof, alloys thereof, or any combination thereof.

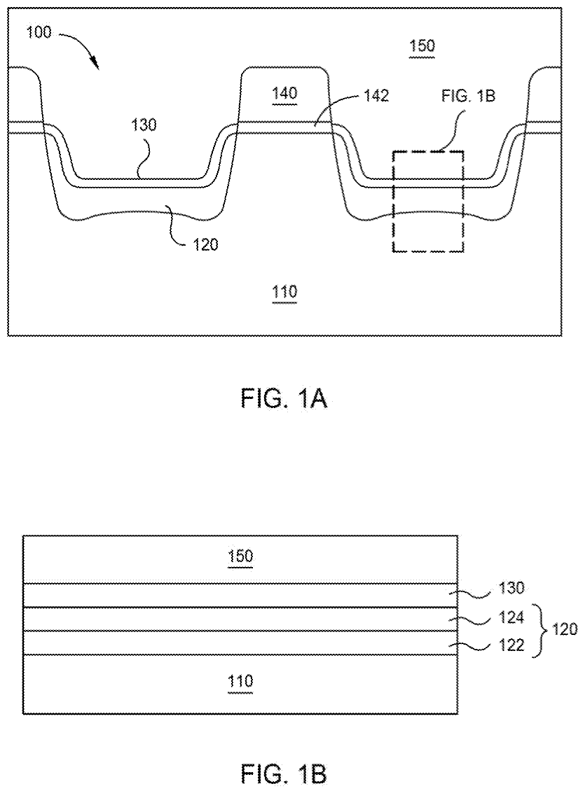

FIG. 1A depicts a schematic, cross-sectional view of a device 100, such as a pMOS transistor source/drain contact within a metal-oxide-semiconductor field-effect transistor (MOSFET), containing a germanium-containing film 120 disposed on the surface of a substrate 110, and a silicide film 130 disposed on the germanium-containing film 120. In some examples, the germanium-containing film 120 is a source/drain film and can include one, two, or more layers of the same or different compositions.

The terms “substrate” and “wafer” as used herein are intended to broadly cover any object that can be processed in a processing chamber. For example, the wafer or substrate 110 may be any substrate capable of having material deposited thereon, such as a silicon substrate, for example silicon (doped or undoped), crystalline silicon (e.g., Si<100> or Si<111>), silicon oxide, strained silicon, doped or undoped polysilicon, or the like, germanium, a III-V compound substrate, a silicon germanium (SiGe) substrate, a silicon germanium carbide (SiGeC) substrate, a silicon germanium oxide (SiGeO) substrate, a silicon germanium oxynitride (SiGeON) substrate, a silicon carbide (SiC) substrate, a silicon carbonitride (SiCN) substrate, a silicon carbonoxide (SiCO), an epi substrate, a silicon-on-insulator (SOI) substrate, a carbon doped oxide, a silicon nitride, a display substrate such as a liquid crystal display (LCD), a plasma display, an electro luminescence (EL) lamp display, a solar array, solar panel, a light emitting diode (LED) substrate, a patterned or non-patterned semiconductor wafer, glass, sapphire, or any other materials such as metals, metal alloys, and other conductive materials. The wafer or substrate 110 may be a planar substrate or a patterned substrate. Patterned substrates are substrates that include electronic features formed into or onto a processing surface of the substrate. The substrate 110 may include multiple layers, or include, for example, partially fabricated devices such as transistors, flash memory devices, and the like. In one or more examples, the substrate 110 can be or include a monocrystalline silicon-germanium (SiGe) wafer or substrate. In other examples, the substrate 110 is a monocrystalline silicon wafer or substrate, such as a P-doped silicon wafer or substrate.

The segments of germanium-containing film 120 are bridged by a gate device 140 disposed therebetween and on or over the substrate 110, as depicted in FIG. 1A. One or more intermediate layers 142 can be disposed between the substrate 110 and the gate device 140. The intermediate layer 142 can be or include silicon oxide, silicon nitride, silicon oxynitride, or combinations thereof. Although not shown, the gate device 140 (e.g., metal gate) can include a gate layer formed on a gate oxide layer disposed on the substrate 110 and also include off-set layers deposited on the sides of the gate. A dielectric layer 150 is deposited or otherwise over the gate device 140 and the silicide film 130. The dielectric layer 150 can be or contain one or more of silicon oxide, silicon nitride, silicon oxynitride, or any combination thereof.

FIG. 1B depicts a close-up view of a portion of the device 100 illustrated in FIG. 1A, as described and discussed in one or more embodiments. The germanium-containing film 120 can include one, two, three, four, or more layers of the same or different compositions. As depicted in FIG. 1B, the germanium-containing film 120 contains two layers, such as a first germanium-containing layer 122 disposed on the substrate 110 and a second germanium-containing layer 124 disposed on the first germanium-containing layer 122. In some examples, the germanium-containing film 120, as well as each independent germanium-containing layer 122, 124, can be or include germanium boride, germanium tin boride, silicon germanium boride, germanium gallium boride, silicon germanium gallium boride, dopants thereof, alloys thereof, or any combination thereof. In one or more examples, the first germanium-containing layer 122 contains silicon germanium boride and the second germanium-containing layer 124 contains germanium boride.

In one or more examples, the germanium-containing film 120 or any germanium-containing layer thereof (e.g., germanium-containing layer 122, 124, or other layers) can be selectively grown, deposited, and/or otherwise formed on the surface of a substrate 110. In some examples, the germanium-containing film 120 or any germanium-containing layer thereof can be formed by implanting dopant ions into the surface of the substrate 110. In other examples, the germanium-containing film 120 or any germanium-containing layer thereof can be formed by depositing a first layer and then thermal processing to diffuse germanium atoms from the substrate 110 into the deposited layer.

The germanium-containing film 120 or any germanium-containing layer thereof (e.g., germanium-containing layer 122, 124, or other layers) can be deposited to any desirable thickness, depending on where and how the silicide film is used on the substrate or device. The germanium-containing film 120 or any germanium-containing layer thereof (e.g., germanium-containing layer 122, 124, or other layers) can independently have a thickness of about 1 nm, about 2 nm, about 3 nm, about 5 nm, about 10 nm, about 15 nm, about 20 nm, or about 25 nm to about 30 nm, about 40 nm, about 50 nm, about 60 nm, about 80 nm, about 100 nm, about 120 nm, about 150 nm, about 200 nm, or thicker. For example, the germanium-containing film 120 or any germanium-containing layer thereof (e.g., germanium-containing layer 122, 124, or other layers) can independently have a thickness of about 1 nm to about 200 nm, about 2 nm to about 200 nm, about 3 nm to about 200 nm, about 5 nm to about 200 nm, about 5 nm to about 180 nm, about 5 nm to about 150 nm, about 5 nm to about 120 nm, about 5 nm to about 100 nm, about 5 nm to about 80 nm, about 5 nm to about 50 nm, about 5 nm to about 40 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 20 nm to about 150 nm, about 20 nm to about 120 nm, about 20 nm to about 100 nm, about 20 nm to about 80 nm, about 20 nm to about 50 nm, about 20 nm to about 40 nm, or about 20 nm to about 30 nm.

Once the germanium-containing film 120 is deposited or otherwise formed on the substrate 110, the silicide film 130 is deposited or otherwise formed on the germanium-containing film 120. In one or more embodiments, the substrate 110 containing germanium-containing film 120 is introduced and/or positioned within a processing chamber, such as a chemical vapor deposition (CVD) chamber, an epi-chamber, or an atomic layer deposition (ALD) chamber. The substrate 110 is heated to and maintained at a substrate temperature of about 400° C. or less and exposed one or more metal precursors and one or more silicon precursors during the vapor deposition process to forming the silicide film 130 on the germanium-containing film 120. In one or more examples, the vapor deposition process is a CVD process and the metal precursor and the silicon precursor are simultaneously introduced into the processing chamber and exposed to the substrate 110. In other examples, the vapor deposition process is an ALD process and the metal precursor and the silicon precursor are sequentially introduced into the processing chamber and exposed to the substrate 110.

The substrate temperature can be about 25° C., about 50° C., about 80° C., about 100° C., about 120° C., about 150° C., about 180° C., about 200° C., about 220° C., about 250° C., about 280° C., or about 300° C. to about 320° C., about 340° C., about 350° C., about 360° C., about 380° C., about 390° C., about 400° C., about 450° C., about 500° C., about 550° C., about 600° C., about 650° C., or about 700° C. For example, the substrate temperature can be about 25° C. to about 700° C., about 25° C. to about 600° C., about 50° C. to about 600° C., about 100° C. to about 600° C., about 150° C. to about 600° C., about 200° C. to about 600° C., about 220° C. to about 600° C., about 240° C. to about 600° C., about 250° C. to about 600° C., about 280° C. to about 600° C., about 300° C. to about 600° C., about 350° C. to about 600° C., about 400° C. to about 600° C., about 450° C. to about 600° C., about 25° C. to about 500° C., about 50° C. to about 500° C., about 100° C. to about 500° C., about 150° C. to about 500° C., about 200° C. to about 500° C., about 220° C. to about 500° C., about 240° C. to about 500° C., about 250° C. to about 500° C., about 280° C. to about 500° C., about 300° C. to about 500° C., about 350° C. to about 500° C., about 400° C. to about 500° C., about 25° C. to about 400° C., about 50° C. to about 400° C., about 100° C. to about 400° C., about 150° C. to about 400° C., about 200° C. to about 400° C., about 220° C. to about 400° C., about 240° C. to about 400° C., about 250° C. to about 400° C., about 280° C. to about 400° C., about 300° C. to about 400° C., about 350° C. to about 400° C., about 25° C. to less than 400° C., about 50° C. to less than 400° C., about 100° C. to less than 400° C., about 150° C. to less than 400° C., about 200° C. to less than 400° C., about 220° C. to less than 400° C., about 240° C. to less than 400° C., about 250° C. to less than 400° C., about 280° C. to less than 400° C., about 300° C. to less than 400° C., about 350° C. to less than 400° C., about 25° C. to about 350° C., about 50° C. to about 350° C., about 100° C. to about 350° C., about 150° C. to about 350° C., about 200° C. to about 350° C., about 220° C. to about 350° C., about 240° C. to about 350° C., about 250° C. to about 350° C., about 280° C. to about 350° C., about 300° C. to about 500° C., about 300° C. to about 450° C., about 300° C. to about 400° C., about 300° C. to about 350° C., about 25° C. to about 300° C., about 50° C. to about 300° C., about 100° C. to about 300° C., about 150° C. to about 300° C., about 200° C. to about 300° C., about 220° C. to about 300° C., about 240° C. to about 300° C., about 250° C. to about 300° C., or about 280° C. to about 300° C.

In some embodiments, the silicide film 130 is formed or otherwise deposited in two or more operations, where each operation includes a deposition process performed at different temperatures. For example, a first portion of the silicide film 130 is formed or otherwise deposited at a first temperature, then a second portion of the silicide film 130 is formed or otherwise deposited at a second temperature. The first temperature can be less than or greater than the second temperature. In one or more examples, the first temperature is less than the second temperature. The first temperature and the second temperature can independently be any of the substrate temperatures or process temperatures described or discussed herein. In some examples, the first temperature can be about 100° C. to about 450° C., such as about 250° C. to about 400° C., and the second temperature can be about 300° C. to about 600° C., such as about 400° C. to about 500° C.

In one or more embodiments, the silicide film 130 is formed on the germanium-containing film 120 by reacting the metal precursor and a portion of the germanium-containing film 120 to produce an intermediate layer, such as a metal germanium or germanide layer. The silicon precursor and the metal germanium or germanide layer react to produce the silicide film 130. The silicide film 130 can be or include one or more layers of one or more metal germanium silicides or metal germanide silicides, such as titanium germanium silicide, nickel germanium silicide, chromium germanium silicide, cobalt germanium silicide, platinum germanium silicide, palladium germanium silicide, molybdenum germanium silicide, tungsten germanium silicide, dopants thereof, alloys thereof, or any combination thereof.

Without wishing to be bound by theory, it is believed that at some low temperature, the silicon precursor is initially not thermally activated to grow or deposit silicon onto the germanium-containing surface (e.g., germanium-containing film 120), but the metal (e.g., Ti, Ni, Cr) precursor reacts with the germanium in the germanium-containing surface and forms a thin metal germanide or germanium layer or film, such as an intermediate layer of film. Once the metal germanide or germanium layer or film is formed, the silicon precursor absorbs thereto and diffuses into and/or through the metal germanide or germanium layer or film and reacts with the metal in therein to produce a metal germanide or germanium silicide layer or film. Also, without wishing to be bound by theory, it is believed that silicon within the metal germanide or germanium silicide layer or film prevents or greatly decreases further reaction of the metal with germanium in the underlying germanium-containing film, which eliminates or reduces germanium migration or erosion, and therefore provides a metal germanide or germanium silicide layer or film that is smooth and conformal.

In other embodiments, the silicide film 130 can be or include one or more layers of one or more metal silicides, such as titanium silicide, nickel silicide, chromium silicide, cobalt silicide, platinum silicide, palladium silicide, molybdenum silicide, tungsten silicide, dopants thereof, alloys thereof, or any combination thereof. The metal silicides can be free, or substantially free, of germanium.

In one or more embodiments, the silicide film 130 has a thickness of about 1 nm, about 2 nm, about 3 nm, about 5 nm, or about 8 nm to about 10 nm, about 12 nm, about 15 nm, about 18 nm, about 20 nm, about 22 nm, about 25 nm, about 30 nm, about 40 nm, or about 50 nm. For example, the silicide film 130 has a thickness of about 1 nm to about 50 nm, about 1 nm to about 40 nm, about 1 nm to about 30 nm, about 1 nm to about 25 nm, about 1 nm to about 20 nm, about 1 nm to about 18 nm, about 1 nm to about 15 nm, about 1 nm to about 12 nm, about 1 nm to about 10 nm, about 1 nm to about 8 nm, about 1 nm to about 5 nm, about 1 nm to about 3 nm, about 2 nm to about 25 nm, about 2 nm to about 20 nm, about 2 nm to about 18 nm, about 2 nm to about 15 nm, about 2 nm to about 12 nm, about 2 nm to about 10 nm, about 2 nm to about 8 nm, about 2 nm to about 5 nm, about 3 nm to about 25 nm, about 3 nm to about 20 nm, about 3 nm to about 18 nm, about 3 nm to about 15 nm, about 3 nm to about 12 nm, about 3 nm to about 10 nm, about 3 nm to about 8 nm, about 3 nm to about 5 nm, about 5 nm to about 50 nm, about 5 nm to about 40 nm, about 5 nm to about 30 nm, about 5 nm to about 25 nm, about 5 nm to about 20 nm, about 5 nm to about 18 nm, about 5 nm to about 15 nm, about 5 nm to about 12 nm, about 5 nm to about 10 nm, or about 5 nm to about 8 nm.

The silicide film 130, as described and discussed herein, is deposited or otherwise formed as a conformal film with a smooth surface (low roughness surface). The silicide film 130, can have a conformality of about 0%, about 0.5%, about 1%, about 2%, about 3%, about 4%, about 5%, about 6%, about 7%, about 8%, about 9%, or about 10% to about 12%, about 15%, about 18%, about 20%, about 22%, about 25%, about 28%, about 30%, about 32%, about 35%, about 40%, about 45%, about 48%, or about 50% of an average thickness of the silicide film 130. For example, the silicide film 130, can have a conformality of about 0% to about 50%, about 1% to about 50%, about 3% to about 50%, about 5% to about 50%, about 10% to about 50%, about 15% to about 50%, about 20% to about 50%, about 25% to about 50%, about 30% to about 50%, about 0% to about 40%, about 1% to about 40%, about 3% to about 40%, about 5% to about 40%, about 10% to about 40%, about 15% to about 40%, about 20% to about 40%, about 25% to about 40%, about 30% to about 40%, about 0% to about 30%, about 1% to about 30%, about 3% to about 30%, about 5% to about 30%, about 10% to about 30%, about 15% to about 30%, about 20% to about 30%, about 25% to about 30%, about 0% to about 25%, about 1% to about 25%, about 3% to about 25%, about 5% to about 25%, about 10% to about 25%, about 15% to about 25%, about 20% to about 25%, about 0% to about 20%, about 1% to about 20%, about 3% to about 20%, about 5% to about 20%, about 10% to about 20%, about 15% to about 20%, about 18% to about 20%, about 0% to about 15%, about 1% to about 15%, about 3% to about 15%, about 5% to about 15%, about 8% to about 15%, about 10% to about 15%, about 0% to about 10%, about 1% to about 10%, about 2% to about 10%, about 3% to about 10%, about 4% to about 10%, about 5% to about 10%, about 6% to about 10%, about 7% to about 10%, about 8% to about 10%, about 0% to about 5%, about 1% to about 5%, about 2% to about 5%, or about 3% to about 5% of an average thickness of the silicide film 130.

The silicide film 130 can have a metal concentration (Ti, Ni, Cr, Mo, W, Pd, Pt, another metal, or any combination thereof) of about 10 atomic percent (at %), about 20 at %, about 25 at %, about 30 at %, about 35 at %, about 40 at %, or about 45 at % to about 50 at %, about 60 at %, about 70 at %, about 80 at %, or about 90 at %. For example, the silicide film 130 can have a metal concentration (Ti, Ni, Cr, Mo, W, Pd, Pt, another metal, or any combination thereof) of about 10 at % to about 90 at %, about 10 at % to about 80 at %, about 10 at % to about 70 at %, about 10 at % to about 60 at %, about 10 at % to about 50 at %, about 20 at % to about 90 at %, about 20 at % to about 80 at %, about 20 at % to about 70 at %, about 20 at % to about 60 at %, about 20 at % to about 50 at %, about 30 at % to about 90 at %, about 30 at % to about 80 at %, about 30 at % to about 70 at %, about 30 at % to about 60 at %, or about 30 at % to about 50 at %.

The can have a germanium concentration of 0 at %, about 1 at %, about 2 at %, about 5 at %, about 8 at %, about 10 at %, about 15 at %, about 18 at %, about 20 at %, about 25 at %, about 30 at %, about 35 at %, about 40 at %, or about 45 at % to about 50 at %, about 60 at %, about 70 at %, about 80 at %, or about 90 at %. For example, the silicide film 130 can have a germanium concentration of 0 at % to about 90 at %, 0 at % to about 70 at %, 0 at % to about 50 at %, 0 at % to about 40 at %, 0 at % to about 30 at %, 0 at % to about 20 at %, 0 at % to about 10 at %, 0 at % to about 5 at %, 0 at % to about 2 at %, 0 at % to about 1 at %, 0 at % to about 0.5 at %, about 20 at % to about 90 at %, about 20 at % to about 70 at %, about 20 at % to about 50 at %, about 20 at % to about 40 at %, about 20 at % to about 30 at %, about 30 at % to about 90 at %, about 30 at % to about 70 at %, about 30 at % to about 50 at %, about 30 at % to about 40 at %, about 30 at % to about 35 at %, about 40 at % to about 90 at %, about 40 at % to about 70 at %, about 40 at % to about 50 at %, or about 40 at % to about 45 at %.

The silicide film 130 can have a silicon concentration of about 0.1 at %, about 0.5 at %, about 1 at %, about 2 at %, about 5 at %, about 8 at %, about 10 at %, about 15 at %, about 18 at %, about 20 at %, about 25 at %, about 30 at %, about 35 at %, about 40 at %, or about 45 at % to about 50 at %, about 60 at %, about 70 at %, about 80 at %, or about 90 at %. For example, the silicide film 130 can have a silicon concentration of about 0.1 at % to about 90 at %, about 0.1 at % to about 70 at %, about 0.1 at % to about 50 at %, about 0.1 at % to about 40 at %, about 0.1 at % to about 30 at %, about 0.1 at % to about 20 at %, about 0.1 at % to about 10 at %, about 0.1 at % to about 5 at %, about 0.1 at % to about 2 at %, about 0.1 at % to about 1 at %, about 0.1 at % to about 0.5 at %, about 20 at % to about 90 at %, about 20 at % to about 70 at %, about 20 at % to about 50 at %, about 20 at % to about 40 at %, about 20 at % to about 30 at %, about 30 at % to about 90 at %, about 30 at % to about 70 at %, about 30 at % to about 50 at %, about 30 at % to about 40 at %, about 30 at % to about 35 at %, about 40 at % to about 90 at %, about 40 at % to about 70 at %, about 40 at % to about 50 at %, or about 40 at % to about 45 at %.

In one or more embodiments, the silicide film 130 includes or contains one or more metal silicides with a metal:silicon (M:Si) ratio of about 0.5, about 0.8, or about 1 to about 1.2, about 1.5, about 1.8, or about 2. The M:Si ratio is the atomic ratio of metal atoms to silicon atoms, where the metal atoms can be Ti, Ni, Cr, Mo, W, Pd, Pt, another metal, or any combination thereof. For example, the silicide film 130 includes or contains one or more metal silicides with an M:Si ratio of about 0.5 to about 2, about 0.5 to about 1.8, about 0.5 to about 1.5, about 0.5 to about 1.2, about 0.5 to about 1, about 0.5 to about 0.8, about 0.8 to about 2, about 0.8 to about 1.8, about 0.8 to about 1.5, about 0.8 to about 1.2, about 0.8 to about 1, about 1 to about 2, about 1 to about 1.8, about 1 to about 1.5, or about 1 to about 1.2.

In other embodiments, the silicide film 130 includes or contains one or more metal germanium silicides (or metal germanide silicides) with a metal:germanium-silicon (M:Ge—Si) ratio of about 0.5, about 0.8, or about 1 to about 1.2, about 1.5, about 1.8, or about 2. The M:Ge—Si ratio is the atomic ratio of metal atoms to the combination of germanium and silicon atoms, where the metal atoms can be Ti, Ni, Cr, Mo, W, Pd, Pt, another metal, or any combination thereof. For example, the silicide film 130 includes or contains one or more metal silicides with an M:Ge—Si ratio of about 0.5 to about 2, about 0.5 to about 1.8, about 0.5 to about 1.5, about 0.5 to about 1.2, about 0.5 to about 1, about 0.5 to about 0.8, about 0.8 to about 2, about 0.8 to about 1.8, about 0.8 to about 1.5, about 0.8 to about 1.2, about 0.8 to about 1, about 1 to about 2, about 1 to about 1.8, about 1 to about 1.5, or about 1 to about 1.2. The combination of germanium and silicon atoms (Ge—Si) can have a germanium:silicon (Ge:Si) ratio of about 0.1, about 0.5, about 0.8, about 1, about 1.5, about 2, about 2.5, or about 3 to about 3.5, about 4, about 4.5, about 5, about 6, about 7, about 8, about 9, or about 10, based on the atomic ratio of germanium atoms to silicon atoms. For example, the Ge:Si ratio can be about 0.1 to about 10, about 0.1 to about 8, about 0.1 to about 6, about 0.1 to about 5, about 0.1 to about 4, about 0.1 to about 3, about 0.1 to about 2, about 0.1 to about 1.5, about 0.1 to about 1, about 0.1 to about 0.8, about 0.1 to about 0.5, about 0.5 to about 10, about 0.5 to about 8, about 0.5 to about 6, about 0.5 to about 5, about 0.5 to about 4, about 0.5 to about 3, about 0.5 to about 2, about 0.5 to about 1.5, about 0.5 to about 1, about 0.5 to about 0.8, about 1 to about 10, about 1 to about 8, about 1 to about 6, about 1 to about 5, about 1 to about 4, about 1 to about 3, about 1 to about 2, about 1 to about 1.5, about 2 to about 10, about 2 to about 8, about 2 to about 6, about 2 to about 5, about 2 to about 4, or about 2 to about 3.

The silicide films 130, such as a metal silicide film or a metal germanide silicide film (also known as metal germanium silicide film), deposited by the methods described and discussed herein, are smoother and more conformal (better morphology) compared to traditional metal silicide films or metal germanide films deposited or formed by traditionally processes.

In one or more embodiments, the silicide film is deposited or otherwise formed by a CVD process, an ALD process, or other vapor deposition process. In one or more examples, a substrate having a germanium-containing surface or film (e.g., source-drain layers or regions) is heated to a deposition temperature and exposed to a deposition gas while depositing the silicide film on the germanium-containing surface. In one or more embodiments, the deposition gas contains one or more silicon precursors and one or more titanium precursors (and/or other metal precursors). In some examples, instead of the titanium precursor, other metal precursors, such as a cobalt precursor, a molybdenum precursor, a nickel precursor, a chromium precursor, a platinum precursor, a palladium precursor, a tungsten precursor, or any combination thereof, are used during the deposition process.

During the vapor deposition process, the precursors can have a variety of flow rates depending on process conditions (e.g., process temperature, process pressure, vapor pressure of precursor) and desired growth rate. One or more carrier gases can accompany or be combined with any of the precursors. One or more purge gases can be used to remove excess precursors or reagents, by-products, contaminants, and/or other materials after deposition processes or operations therebetween (e.g., during an ALD cycle). Exemplary carrier gases and/or purge gases can be or include, but are not limited to, nitrogen, hydrogen, argon, helium, or any combination thereof. In one or more examples, the titanium or other metal precursor can have a flow rate of about 0.1 sccm, about 1 sccm, about 2 sccm, about 5 sccm, about 10 sccm, about 20 sccm, about 50 sccm, or about 100 sccm to about 150 sccm, about 200 sccm, about 300 sccm, about 400 sccm, about 500 sccm, about 1,000 sccm, or greater. In other examples, the titanium or other metal precursor can have a flow rate of about 0.5 mg/min, about 1 mg/min, about 5 mg/min, about 10 mg/min or about 20 mg/min to about 25 mg/min, about 30 mg/min, about 50 mg/min, about 65 mg/min, about 80 mg/min, about 100 mg/min, or greater. The silicon precursor can have a flow rate of about 0.1 sccm, about 1 sccm, about 10 sccm, about 30 sccm, or about 50 sccm to about 80 sccm, about 100 sccm, about 150 sccm, about 200 sccm, about 250 sccm, about 300 sccm, about 500 sccm, or greater.

In one or more embodiments, the metal precursor is or contains one or more titanium precursors, one or more nickel precursors, one or more chromium precursors, or any combination thereof. For example, the metal precursor is or contains one or more metal halide precursors (e.g., halide of titanium, nickel, chromium, cobalt, platinum, palladium, molybdenum, or tungsten), such as a titanium halide, a nickel halide, or a chromium halide. Exemplary metal halide precursors can be or include titanium tetrachloride, titanium tetrafluoride, titanium tetrabromide, titanium tetraiodide, nickel chloride, chromium chloride, cobalt chloride, platinum chloride, palladium chloride, molybdenum chloride, tungsten chloride. The silicon precursor can be or include one or more of silane, disilane, trisilane, tetrasilane, pentasilane, hexasilane, dichlorosilane, tetracholorosilane, hexacholorodisilane, substitutes thereof, or any combination thereof. In one or more examples, the metal precursor contains titanium tetrachloride and the silicon precursor contains silane, disilane, trisilane, or any combination thereof.

In deposition processes described and discussed herein, the silicide films 130 contain or include a metal germanium silicide (e.g., titanium, nickel, chromium, cobalt, platinum, palladium, molybdenum, or tungsten) and/or a metal silicide which is deposited or otherwise formed by one or more deposition processes. Exemplary deposition processes can be or include CVD processes, ALD processes, atomic layer epitaxy (ALE) processes. Chemical vapor deposition includes the use of many techniques, such as thermal CVD, plasma-assisted CVD (PA-CVD), atomic layer CVD (ALCVD), organometallic or metalorganic CVD (OMCVD or MOCVD), laser-assisted CVD (LA-CVD), ultraviolet CVD (UV-CVD), hot-wire (HWCVD), reduced-pressure CVD (RP-CVD), ultra-high vacuum CVD (UHV-CVD), and/or other processes. In one or more embodiments, thermal CVD, PE-CVD, thermal ALD, or PE-ALD is used to epitaxially grow, form, or otherwise deposit the silicide films 130, as described and discussed herein.

The deposition or formation processes for depositing the silicide films can be performed in a CVD, ALD, ALE, and other processing or deposition chambers and systems. The processing or deposition chamber brings the precursors or sources into contact with a heated substrate on which the silicide films containing a metal silicide or metal germanide silicide are deposited or formed. The vapor deposition processes can be conducted at a pressure in a range from about 0.1 Torr to about 500 Torr, about 1 Torr to about 400 Torr, or about 5 Torr to about 300 Torr. The processing/deposition chambers or systems that can be used to deposit or otherwise form the silicide films can be or include an Epi Centura® thermal chamber or system, a Centura® RP (remote plasma) EPI chamber or system, and/or a Poly Gene chamber or system, all commercially available from Applied Materials, Inc., located in Santa Clara, Calif.

In one or more embodiments, a source/drain device contains a silicide film disposed on a germanium-containing film, as described and discussed herein. The germanium-containing film contains or includes one, two, or more of germanium boride, germanium tin boride, silicon germanium boride, germanium gallium boride, silicon germanium gallium boride, dopants thereof, alloys thereof, or any combination thereof.

Embodiments of the present disclosure further relate to any one or more of the following paragraphs 1-26:

1. A method of processing a substrate, comprising: positioning the substrate within a processing chamber, wherein the substrate comprises a germanium-containing film; heating the substrate to a temperature of about 100° C. to about 600° C.; and exposing the substrate to a metal precursor and a silicon precursor during a vapor deposition process and forming a silicide film on the germanium-containing film, wherein the silicide film has a conformality of about 1% to about 50% of an average thickness of the silicide film.

2. A method of processing a substrate, comprising: positioning the substrate within a processing chamber, wherein the substrate comprises a germanium-containing film; heating the substrate to a temperature of about 200° C. to about 400° C.; exposing the substrate to a metal precursor and a silicon precursor during a vapor deposition process; reacting the metal precursor and a portion of the germanium-containing film to produce a metal germanium layer; and reacting the silicon precursor and the metal germanium layer to produce a silicide film on the germanium-containing film.

3. A source/drain device, comprising: a germanium-containing film comprising germanium boride, germanium tin boride, silicon germanium boride, germanium gallium boride, silicon germanium gallium boride, dopants thereof, alloys thereof, or any combination thereof; and a silicide film comprising titanium germanium silicide and disposed on the germanium-containing film, wherein the silicide film has a conformality of about 1% to about 20% of an average thickness of the silicide film.

4. The method and/or the source/drain device according to any one of paragraphs 1-3, wherein forming the silicide film on the germanium-containing film further comprises: reacting the metal precursor and a portion of the germanium-containing film to produce a metal germanium layer; and reacting the silicon precursor and the metal germanium layer to produce the silicide film.

5. The method and/or the source/drain device according to paragraph 4, wherein the silicide film comprises titanium germanium silicide, nickel germanium silicide, chromium germanium silicide, cobalt germanium silicide, platinum germanium silicide, palladium germanium silicide, molybdenum germanium silicide, tungsten germanium silicide, dopants thereof, alloys thereof, or any combination thereof.

6. The method and/or the source/drain device according to any one of paragraphs 1-5, wherein forming the silicide film on the germanium-containing film further comprises: reacting the metal precursor and a portion of the germanium-containing film to produce a metal germanium layer; then co-flowing the metal precursor and the silicon precursor into the processing chamber; and exposing the metal germanium layer to a mixture comprising the metal precursor and the silicon precursor to produce the silicide film on the metal germanium layer.

7. The method and/or the source/drain device according to paragraph 6, wherein the metal germanium layer is produced at a first temperature and the silicide film is produced at a second temperature which is greater than the first temperature.

8. The method and/or the source/drain device according to paragraph 7, wherein the first temperature is about 100° C. to about 450° C. and the second temperature is about 300° C. to about 600° C.

9. The method and/or the source/drain device according to paragraph 8, wherein the first temperature is about 250° C. to about 400° C. and the second temperature is about 400° C. to about 500° C.

10. The method and/or the source/drain device according to any one of paragraphs 1-9, wherein the silicide film comprises titanium germanium silicide.

11. The method and/or the source/drain device according to any one of paragraphs 1-10, wherein the metal precursor comprises a halide of titanium, nickel, chromium, cobalt, platinum, palladium, molybdenum, or tungsten.

12. The method and/or the source/drain device according to any one of paragraphs 1-11, wherein the silicon precursor comprises silane, disilane, trisilane, tetrasilane, pentasilane, hexasilane, dichlorosilane, tetracholorosilane, hexacholorodisilane, substitutes thereof, or any combination thereof.

13. The method and/or the source/drain device according to any one of paragraphs 1-12, wherein the silicon precursor comprises dichlorosilane, silane, disilane, trisilane, or any combination thereof, and wherein the metal precursor comprises titanium tetrachloride.

14. The method and/or the source/drain device according to any one of paragraphs 1-13, wherein the substrate is heated to a temperature of about 250° C. to less than 500° C.

15. The method and/or the source/drain device according to any one of paragraphs 1-14, wherein the substrate is heated to a temperature of about 300° C. to about 450° C.

16. The method and/or the source/drain device according to any one of paragraphs 1-15, wherein the silicide film has a conformality of about 5% to about 30% of the average thickness of the silicide film.

17. The method and/or the source/drain device according to any one of paragraphs 1-16, wherein the silicide film has a thickness of about 1 nm to about 50 nm.

18. The method and/or the source/drain device according to any one of paragraphs 1-17, wherein the germanium-containing film has a thickness of about 1 nm to about 200 nm.

19. The method and/or the source/drain device according to any one of paragraphs 1-18, wherein the vapor deposition process is a chemical vapor deposition process and the metal precursor and the silicon precursor are simultaneously introduced into the processing chamber and exposed to the substrate.

20. The method and/or the source/drain device according to paragraph 19, wherein the metal precursor and the silicon precursor are co-flowed together into the processing chamber and exposed to the substrate.

21. The method and/or the source/drain device according to any one of paragraphs 1-20, wherein the vapor deposition process is an atomic layer deposition process and the metal precursor and the silicon precursor are sequentially introduced into the processing chamber and exposed to the substrate.

22. The method and/or the source/drain device according to paragraph 21, wherein the atomic layer deposition process further comprises: sequentially exposing the substrate the metal precursor and the silicon precursor to deposit a first metal silicide layer; and then sequentially exposing the substrate the metal precursor and the silicon precursor to deposit multiple metal silicide layers producing the silicide film.

23. The method and/or the source/drain device according to any one of paragraphs 1-22, wherein the germanium-containing film comprises germanium boride, germanium tin boride, silicon germanium boride, germanium gallium boride, silicon germanium gallium boride, dopants thereof, alloys thereof, or any combination thereof.

24. The method and/or the source/drain device according to any one of paragraphs 1-23, wherein the germanium-containing film is a pMOS layer in a source/drain device.

25. The method and/or the source/drain device according to any one of paragraphs 1-24, wherein the silicide film has a conformality of about 1% to about 50% of an average thickness of the silicide film.

26. A source/drain device produced, made, or formed by according the methods of any one of paragraphs 1-25.

While the foregoing is directed to implementations of the disclosure, other and further implementations may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of processing a substrate, comprising:
positioning the substrate within a processing chamber, wherein the substrate comprises a germanium-containing film;
heating the substrate to a temperature of about 100° C. to about 600° C.; and
exposing the substrate to a metal precursor and a silicon precursor during a vapor deposition process and forming a silicide film on the germanium-containing film, wherein the silicide film has a conformality of about 1% to about 50% of an average thickness of the silicide film.

2. The method of claim 1, wherein forming the silicide film on the germanium-containing film further comprises:
reacting the metal precursor and a portion of the germanium-containing film to produce a metal germanium layer; and
reacting the silicon precursor and the metal germanium layer to produce the silicide film.

3. The method of claim 2, wherein the silicide film comprises titanium germanium silicide, nickel germanium silicide, chromium germanium silicide, cobalt germanium silicide, platinum germanium silicide, palladium germanium silicide, molybdenum germanium silicide, tungsten germanium silicide, dopants thereof, alloys thereof, or any combination thereof.

4. The method of claim 1, wherein forming the silicide film on the germanium-containing film further comprises:
reacting the metal precursor and a portion of the germanium-containing film to produce a metal germanium layer; then
co-flowing the metal precursor and the silicon precursor into the processing chamber; and
exposing the metal germanium layer to a mixture comprising the metal precursor and the silicon precursor to produce the silicide film on the metal germanium layer.

5. The method of claim 4, wherein the metal germanium layer is produced at a first temperature and the silicide film is produced at a second temperature which is greater than the first temperature.

6. The method of claim 5, wherein the first temperature is about 100° C. to about 450° C. and the second temperature is about 300° C. to about 600° C.

7. The method of claim 6, wherein the first temperature is about 250° C. to about 400° C. and the second temperature is about 400° C. to about 500° C.

8. The method of claim 1, wherein the silicide film comprises titanium germanium silicide.

9. The method of claim 1, wherein the metal precursor comprises a halide of titanium, nickel, chromium, cobalt, platinum, palladium, molybdenum, or tungsten.

10. The method of claim 1, wherein the silicon precursor comprises silane, disilane, trisilane, tetrasilane, pentasilane, hexasilane, dichlorosilane, tetracholorosilane, hexacholorodisilane, substitutes thereof, or any combination thereof.

11. The method of claim 1, wherein the silicon precursor comprises dichlorosilane, silane, disilane, trisilane, or any combination thereof, and wherein the metal precursor comprises titanium tetrachloride.

12. The method of claim 1, wherein the substrate is heated to a temperature of about 250° C. to less than 500° C.

13. The method of claim 1, wherein the silicide film has a conformality of about 5% to about 30% of the average thickness of the silicide film.

14. The method of claim 1, wherein the silicide film has a thickness of about 1 nm to about 50 nm, and wherein the germanium-containing film has a thickness of about 1 nm to about 200 nm.

15. The method of claim 1, wherein the vapor deposition process is a chemical vapor deposition process and the metal precursor and the silicon precursor are simultaneously introduced into the processing chamber and exposed to the substrate, wherein the metal precursor and the silicon precursor are co-flowed together into the processing chamber and exposed to the substrate.

16. The method of claim 1, wherein the vapor deposition process is an atomic layer deposition process and the metal precursor and the silicon precursor are sequentially introduced into the processing chamber and exposed to the substrate, and wherein the atomic layer deposition process further comprises:
sequentially exposing the substrate the metal precursor and the silicon precursor to deposit a first metal silicide layer; and then
sequentially exposing the substrate the metal precursor and the silicon precursor to deposit multiple metal silicide layers producing the silicide film.

17. The method of claim 1, wherein the germanium-containing film comprises germanium boride, germanium tin boride, silicon germanium boride, germanium gallium boride, silicon germanium gallium boride, dopants thereof, alloys thereof, or any combination thereof, and wherein the germanium-containing film is a pMOS layer in a source/drain device.

18. A method of processing a substrate, comprising:
positioning the substrate within a processing chamber, wherein the substrate comprises a germanium-containing film;
heating the substrate to a temperature of about 200° C. to about 400° C.;
exposing the substrate to a metal precursor and a silicon precursor during a vapor deposition process;
reacting the metal precursor and a portion of the germanium-containing film to produce a metal germanium layer; and
reacting the silicon precursor and the metal germanium layer to produce a silicide film on the germanium-containing film.

19. The method of claim 18, wherein the silicide film comprises titanium germanium silicide, nickel germanium silicide, chromium germanium silicide, cobalt germanium silicide, platinum germanium silicide, palladium germanium silicide, molybdenum germanium silicide, tungsten germanium silicide, dopants thereof, alloys thereof, or any combination thereof, and wherein the silicide film has a conformality of about 1% to about 50% of an average thickness of the silicide film.

20. A source/drain device, comprising:
a germanium-containing film comprising germanium boride, germanium tin boride, silicon germanium boride, germanium gallium boride, silicon germanium gallium boride, dopants thereof, alloys thereof, or any combination thereof; and
a silicide film comprising titanium germanium silicide and disposed on the germanium-containing film, wherein the silicide film has a conformality of about 1% to about 20% of an average thickness of the silicide film.
